(19) United States
(12) Patent Application Publication
(10) Pub. No.: US 2026/0020295 A1
(43) Pub. Date: Jan. 15, 2026

(54) SEMICONDUCTOR DEVICES WITH DRAIN-SOURCE AVALANCHE BREAKDOWN

(71) Applicant: Wolfspeed, Inc., Durham, NC (US)

(72) Inventor: Rahul R. Potera, Apex, NC (US)

(21) Appl. No.: 18/772,731

(22) Filed: Jul. 15, 2024

(51) Int. Cl. H01L 29/06; H01L 29/16; H01L 29/808

(52) U.S. Cl. CPC H10D 62/108; H10D 30/831; H10D 62/106; H10D 62/8325

(57) ABSTRACT

A semiconductor device includes a semiconductor layer having an active region. The semiconductor layer has a first conductivity type. The semiconductor device further includes a plurality of alternating mesa stripes and trenches in the active region, a source metal layer electrically connected with the plurality of mesa stripes, an isolation ring adjacent the active region, the isolation ring having a second conductivity type opposite the first conductivity type, and a doped region in the semiconductor layer, wherein the isolation ring is between the active region and the doped region, the doped region having the second conductivity type and forming a P-N junction with the semiconductor layer. The source metal layer is electrically connected with the doped region.

### TECHNICAL FIELD

The present disclosure relates to semiconductor devices and, more particularly, to vertical power semiconductor devices.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate metal layers, and one or more gate buses and/or gate metal layers that electrically connect the gate pad to the gate metal layers. The gate metal layers are disposed adjacent the respective channel regions. Power JFETs are typically normally-on devices, meaning that a JFET conducts current when a voltage of 0 volts is applied to the gate. When a sufficiently negative voltage (referred to as the threshold voltage, VT) is applied to the gate structure, the channel is pinched off and the JFET ceases to conduct current.

### SUMMARY

A semiconductor device according to some embodiments includes a semiconductor layer having an active region. The semiconductor layer has a first conductivity type. The semiconductor device further includes a plurality of alternating mesa stripes and trenches in the active region, a source metal layer electrically connected with the plurality of mesa stripes, an isolation ring adjacent the active region, the isolation ring having a second conductivity type opposite the first conductivity type, and a doped region in the semiconductor layer, wherein the isolation ring is between the active region and the doped region, the doped region having the second conductivity type and forming a P-N junction with the semiconductor layer. The source metal layer is electrically connected with the doped region.

The doped region may include a ring around the isolation ring.

The doped region may be provided at a bottom surface of a trench between a pair of semiconductor mesas on the semiconductor layer.

The semiconductor device may further include metal silicide layers on upper surfaces of the plurality of mesa stripes, wherein metal silicide layers are not formed on upper surfaces of the pair of semiconductor mesas.

The semiconductor device may further include a metal silicide layer on the doped region, wherein the source metal layer contacts the metal silicide layer.

The semiconductor device may further include an edge termination region adjacent the doped region.

The edge termination region may encircle the active region and the doped region.

A junction field effect semiconductor device according to some embodiments includes a semiconductor layer having an active region, the semiconductor layer having a first conductivity type, a plurality of alternating mesa stripes and trenches in the active region, a plurality of gate regions in respective ones of the trenches, a source metal layer electrically connected with the plurality of mesa stripes, and a doped region in the semiconductor layer adjacent the active region, the doped region having a second conductivity type opposite the first conductivity type and forming a P-N junction with the semiconductor layer. The source metal layer is electrically connected with the doped region.

The semiconductor device may further include an isolation ring adjacent the active region, the isolation ring having a second conductivity type opposite the first conductivity type, wherein the isolation ring is between the doped region and the active region.

The doped region may include a ring around the isolation ring.

The doped region may be provided at a bottom surface of a trench between a pair of semiconductor mesas on the semiconductor layer.

The semiconductor device may further include metal silicide layers on upper surfaces of the plurality of mesa stripes, wherein metal silicide layers are not formed on upper surfaces of the pair of semiconductor mesas.

The semiconductor device may further include a metal silicide layer on the doped region, wherein the source metal layer contacts the metal silicide layer.

The semiconductor device may further include an edge termination region surrounding the doped region.

A semiconductor device according to some embodiments includes a semiconductor layer having an active region, the semiconductor layer having a first conductivity type, a plurality of alternating mesa stripes and trenches in the active region, a source metal layer electrically connected with the plurality of mesa stripes, a doped region in the semiconductor layer outside the active region, the doped region having a second conductivity type opposite the first conductivity type and forming a P-N junction with the semiconductor layer, wherein the source metal layer is electrically connected with the doped region, and an edge termination region adjacent the doped region.

The semiconductor device may further include an isolation ring adjacent the active region, the isolation ring having a second conductivity type opposite the first conductivity type, wherein the isolation ring is between the active region and the doped region.

A semiconductor device according to some embodiments includes a semiconductor layer having an active region, the semiconductor layer having a first conductivity type, a plurality of alternating mesa stripes and trenches in the active region, a source metal layer electrically connected with the plurality of mesa stripes, an isolation ring adjacent the active region, the isolation ring having a second conductivity type opposite the first conductivity type, an edge termination adjacent the isolation ring, and a doped region in the semiconductor layer outside the active region, the doped region having the second conductivity type and forming a P-N junction with the semiconductor layer, wherein the source metal layer is electrically connected with the doped region, and wherein the isolation ring is between the active region and the doped region.

The doped region may include a ring around the isolation ring.

The doped region may be provided at a bottom surface of a trench between a pair of semiconductor mesas on the semiconductor layer.

The semiconductor device may further include a metal silicide layer on the doped region, wherein the source metal layer contacts the metal silicide layer.

The edge termination may include a planar edge termination.

The edge termination may include a plurality of alternating trenches and mesas, and implanted regions beneath the trenches, wherein the implanted regions have the second conductivity type.

### BRIEF DESCRIPTION OF DRAWINGS

FIG. 1 illustrates a cell of a vertical JFET semiconductor device.

FIGS. 2 (A) and 2 (B) illustrate, in plan view, conventional layouts of vertical JFET semiconductor devices.

FIGS. 3, 4 and 5 illustrates a conventional JFET structure.

FIG. 6 is a cross-sectional view of a JFET structure according to some embodiments.

FIG. 7 is a plan view of the JFET structure of FIG. 6.

FIG. 8 is a cross-sectional view of a JFET structure according to some embodiments.

FIG. 9 is a plan view of the JFET structure of FIG. 8.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art. Like reference numbers refer to like elements throughout the description.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

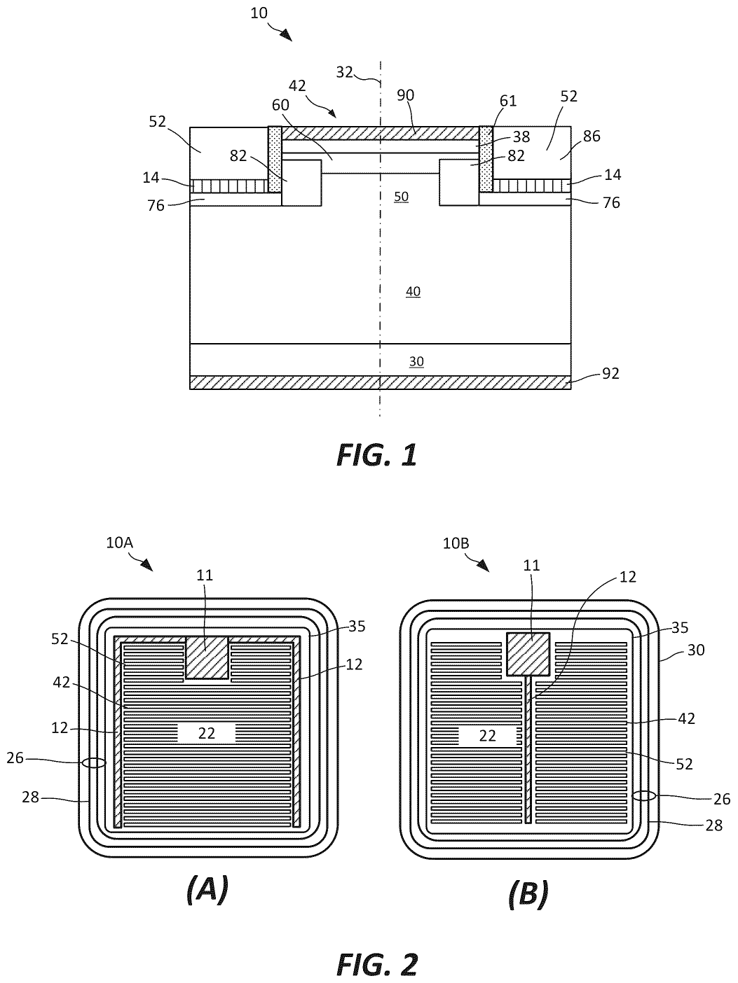

An n-channel vertical JFET structure 10 is shown in FIG. 1. The vertical JFET structure 1 includes an n+ substrate 30 on which an n-drift layer 40 is formed. An n-type channel region 50 is on the drift layer 40, and an n+ source layer 60 is on the channel region 50. An n++ source metal layer 38 is on the n+ source layer 60. A drain ohmic contact 92 is on the substrate 30, and a source metal layer 90 is on the source metal layer 38. The channel region 50, source layer 60 and source metal layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate finger 14 and the gate contact region 76. The insulation layer 86 may be formed from silicon oxide. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length (i.e., the distance carriers travel through the channel from the source to the drain) is chosen based on a trade-off between low on-resistance in the on-state and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30.

FIGS. 2 (A) and 2 (B) illustrate, in plan view, conventional layouts of vertical JFET semiconductor devices 10A and 10B, respectively. Referring to FIGS. 1 and 2 (A), a JFET device 10A is formed on a substrate 30. The device 10A includes an active region 22 in which a plurality of alternating mesa stripes 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A metal silicide region 35 is formed on an upper surface of the device within the active region 22 in areas other than on the mesa stripes 42. The metal silicide region 35, which may for example be nickel silicide, forms the gate fingers 14 within the trenches 52. A gate contact pad 11 is formed on the upper surface of the device 10A within the metal silicide region 35, and a pair of gate buses 12 (also referred to as gate runners 12) extend from the gate contact pad 11 around the outer periphery of the active region 22 adjacent the ends of the mesa stripes 42 and trenches 52 of the device 10A. The gate contact pad 11 and the gate buses 12 may include a conductive material such as a metal silicide and/or a metal layer.

The metal silicide region 35 provides a low resistance current path between the gate buses 12/gate contact pad 11 and the gate fingers 14 (FIG. 1) that are formed within the trenches 52.

The JFET device 10B shown in FIG. 2 (B) is similar to the JFET device 10A shown in FIG. 2 (A), except that the JFET device 10B includes only a single gate bus 12 which extends from the gate contact pad 11 through the center of the active region 22.

In both JFET devices 10A, 10B, a gate voltage applied to the gate contact pad 11 is conducted through the gate bus 12 and metal silicide region 35 to the gate ohmic contacts 14 within the trenches 52.

In a switching power device such as a JFET device, a phenomenon referred to as unclamped inductive switching (UIS) may occur when the device is placed under high reverse bias. UIS occurs when current undesirably flows from the drain of the device back through the gate of the device. This subjects the device simultaneously to high current and high voltage, which dissipates a high amount of power in the device and may cause the device to fail when the UIS current exceeds a threshold limit. The ability to handle UIS current is an important quality of a switching power device.

If UIS current is limited by current crowding and filamentation in a part of the semiconductor structure, UIS weakness can be addressed by making the junction breakdown more uniform so that heat is dissipated more uniformly across the device. If UIS current is limited by the current carrying regions outside the semiconductor device, UIS weakness can be addressed by increasing ampacity at those choke points.

When UIS current is not limited in those ways, then gate-drain UIS current causes a voltage drop across the gate resistance, which biases the gate of the device. At sufficient UIS current, this UIS-induced gate bias can exceed the local threshold voltage (VT) of the device and turn on the channel locally (i.e., in the vicinity of the induced gate bias). The channel current induced by UIS biasing will heat up the device locally creating a hotspot in the device. This further reduces VT and increases leakage near the hotspot. This condition creates a positive feedback loop, referred to as a thermal runaway condition, that can cause the device to fail catastrophically at the hotspot.

The main blocking junction of a JFET device at which drain breakdown happens is the gate-drain PN junction. Most JFETs are normally-on devices that block drain voltage with negative gate bias. In such devices, the gate to drain PN junction is biased at a higher voltage than the source to drain junction, which causes UIS breakdown to be more likely to occur at the gate to drain PN junction.

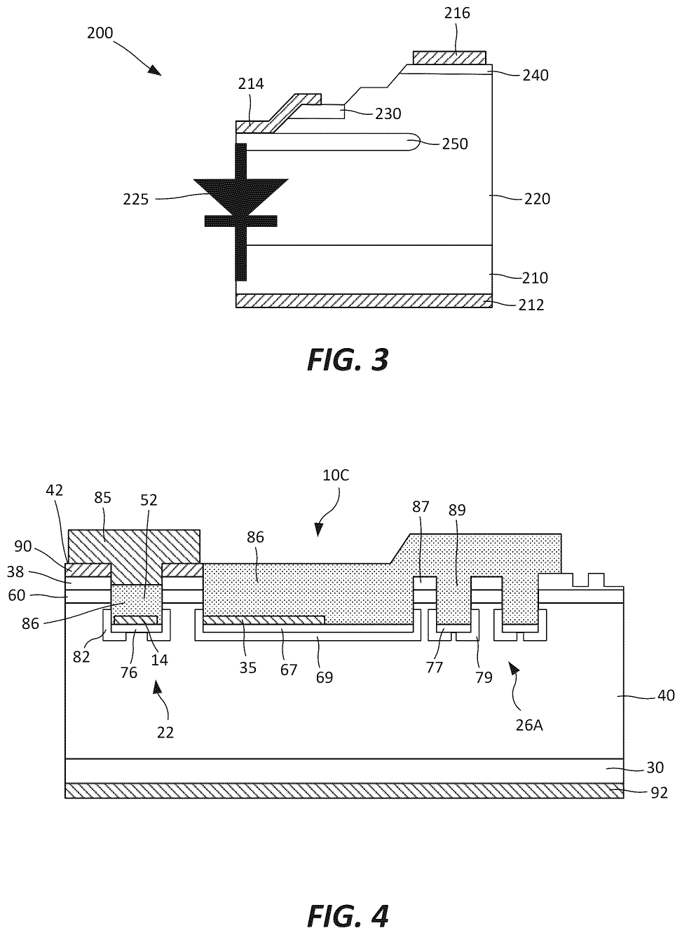

As noted above, with gate-drain breakdown in a JFET, UIS capability is limited either by the ability of the gate to carry current or by positive feedback effects that open the channel during UIS and cause hotspot failure. There exist various JFET designs that have the drain to source PN junction as the main blocking junction, such as the device structure 200 shown in FIG. 3.

In particular the device structure 200 shown in FIG. 3 includes an n+SiC substrate 210 on which an n-SiC drift region 220 is formed. An n+ source region 230 and a p-type gate region 240 are formed on the drift region 220. A buried p-type body region 250 is provided in the drift region. A source metal layer 214 forms an ohmic contact to the source region 230 and to the buried p-type body region 250. A gate metal layer 216 is on the gate region 240 and a drain metal layer 212 is formed on the substrate 210. The buried p-type body region 250 forms a built-in PN junction between the source metal layer 214 and the drain metal layer 212, which allows UIS current to flow from source to drain. However, such devices may have lower transconductance (i.e., a higher chip area for the same VT and drain-source on-resistance, Rdson) than the structure shown in FIG. 1.

Some embodiments described herein provide JFET designs that may have preferential drain-source breakdown junctions which may improve UIS capability without significantly affecting transconductance.

As discussed above, in conventional SIT-type JFET structures such as the structure shown in FIG. 1, drain breakdown may occur at the drain-gate junction. Some embodiments described herein integrate a drain-source breakdown junction into the device. The integrated drain-source junction may be designed to break down at a lower voltage than the drain-gate junction, thereby allowing avalanche current to be carried in the drain-source path. This may increase the capability of the JFET to withstand avalanche current. When only the existing JFET chip area under the gate pad and along the edge termination is used to carry drain-source avalanche current, a certain drain-source avalanche capability can be achieved. However, by adding additional chip area for a drain-source breakdown junction, the avalanche capability can be further increased.

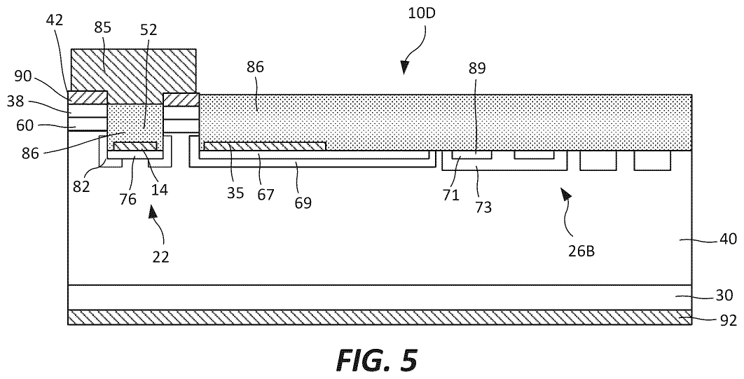

FIG. 4 shows a conventional JFET structure 10C with a mesa-trench edge termination, and FIG. 5 shows a conventional JFET structure 10D with a planar edge termination. In both cases, drain breakdown happens at drain-gate PN junction between the drift layer 40 and the gate regions 82/gate contact region 76.

Referring to FIG. 4, the JFET structure 10C is similar to the structure 10A shown in FIG. 1. FIG. 4 further illustrates the silicide region 35 outside the active region 22. The silicide region contacts a p-well region 67/69 in the drift layer 40 that is formed in the same implant process used to form the gate contact region 76 and the gate regions 82 in the active region 22. FIG. 4 further illustrates a mesa-trench edge termination region 26A that encircles the active region 22 and protects the edge of the device against high electric fields. The silicide region 35 and the edge termination region 26A are covered by the insulation layer 86.

The mesa-trench edge termination region 26A includes one or more mesa 87 and trench 89 structures that are formed in the same fabrication process used to form the mesas 42 and trenches 52 in the active region 22. The mesas 87/trenches 89 are doped with p-type regions 77, 79 in the same process used to form the gate contact region 76 and the gate regions 82 in the active region 22. The doped p-type regions 77, 79 form p-type guard rings around the active region 22.

The doping and spacing of the doped p-type regions 77, 79 may be selected in accordance with conventional design techniques to provide a desired breakdown voltage.

Referring to FIG. 5, the JFET structure 10D is similar to the structure 10A shown in FIG. 1. FIG. 5 also illustrates the silicide region 35 and the p-well region 67/69 outside the active region 22.

FIG. 5 further illustrates a planar edge termination region 26B that encircles the active region 22 and protects the edge of the device against high electric fields. The planar trench edge termination region 26B includes one or more doped p-type regions 71 that form p-type guard rings around the active region 22. The p-type regions 71 may be formed in an optional p-well region 73. The doping and spacing of the p-type regions 71 and the p-well 73 may be selected to provide a desired breakdown voltage.

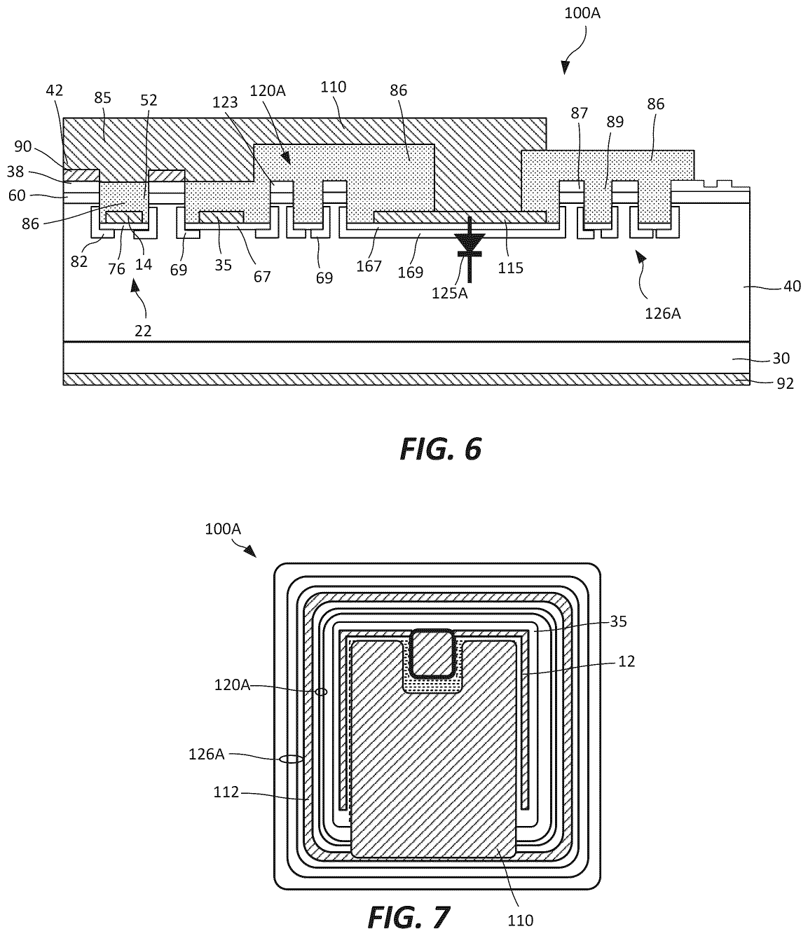

FIGS. 6 and 7 illustrate a SiC JFET structure 100A according to some embodiments. In particular, FIG. 6 is a cross-sectional view and FIG. 7 is a plan view that illustrate a SiC JFET structure 100A in which the source metal layer 85 is connected to a p-well implanted region 167/169 to form a drain-source avalanche PN junction 125A. The p-well implanted region 167/169 is isolated from the active region 22 by an isolation region 120A including one or more trench/mesa isolation rings 123.

The same mesa-etch process used to form the trench 52/mesa 42 structures in the active region 22 can be used to form the trench/mesa isolation rings 123 between the gate p-well regions 76/82 and the source-connected p-well implanted regions 167/169. Thus, the trench/mesa isolation rings 123 may have the same general structure as the trench 52/mesa 42 structures in the active region 22, with p-type sidewall implanted regions 69 in the mesa sidewalls and p-type floor implanted regions 67 in the trenches. The p-type sidewall implanted regions 69 in the mesa sidewalls may be formed in the same implant process used to form the sidewall gate regions 82, and the p-type floor implanted regions 67 in the trenches may be formed in the same implant process used to form the gate contact regions 76.

The isolation region 120A is covered by the insulation layer 86, and an extension 110 of the source metal layer 85 extends over the insulation layer 86 and contacts a metal silicide ohmic contact 115 that is formed on the p-well implanted region 167/169. The drain-source avalanche PN junction 125A is formed at the junction between the p-well implanted region 167/169 and the drift layer 40.

The drain-source avalanche PN junction 125A is formed within the periphery of the edge termination region 126A, which in the device 100 is formed as trench 89/mesa 87 structures with implanted p-type regions formed in the same process as the trench 52/mesa 42 structures in the active region 22.

In the device 100A, drain breakdown can be preferentially initiated at the drain-source junction 125A rather than the drain-gate junction in the active area 22 of the device 100A by designing the trench/mesa isolation rings 123 or the edge-termination 126A to breakdown at a slightly lower voltage (e.g., ˜850V vs 900V for a 750V JFET) than the active cell.

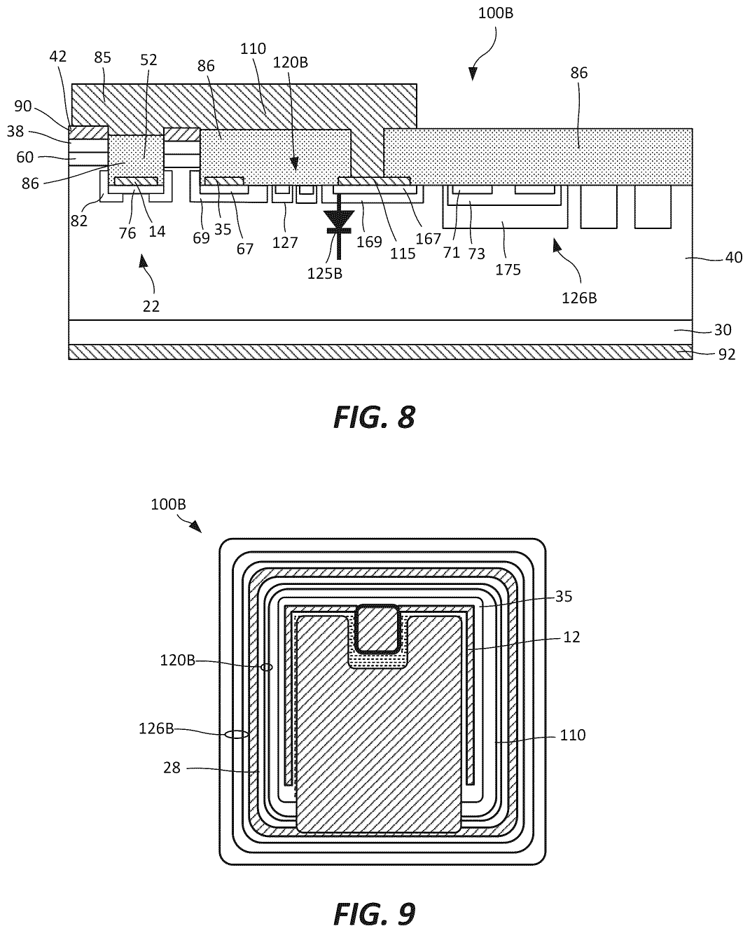

FIGS. 8 and 9 illustrate a SiC JFET structure 100B according to some embodiments. In particular, FIG. 8 is a cross-sectional view and FIG. 9 is a plan view that illustrate a SiC JFET structure 100B in which the source metal layer 85 is connected to a p-well implanted region 167/169 to form a drain-source avalanche PN junction 125B. The p-well implanted region 167/169 is isolated from the active region 22 by an isolation region 120B including one or more planar isolation rings 127.

The same implant process used to form the gate contact region 76/gate regions 82 in the active region 22 can be used to form the planar isolation rings 127 between the gate p-well regions 76/82 and the source-connected p-well implanted regions 167/169. Thus, the planar isolation rings 127 may have the same doping concentrations as the gate p-well regions 76/82 in the active region 22. The p-type implanted regions 169 may be formed in the same implant process used to form the sidewall gate regions 83, and the p-type implanted regions 167 may be formed in the same implant process used to form the gate contact regions 76.

The isolation region 120B is covered by the insulation layer 86, and an extension 110 of the source metal layer 85 extends over the insulation layer 86 and contacts a metal silicide ohmic contact 115 that is formed on the p-well implanted region 167/169. The drain-source avalanche PN junction 125B is formed at the junction between the p-well implanted region 167/169 and the drift layer 40.

The drain-source avalanche PN junction 125B is formed within the periphery of the edge termination region 126B, which in the device 100 is formed as implanted p-type regions 71/73 formed in the same implant process as the implanted regions 167/169 in the isolation region 120B. The implanted regions 71/73 may be formed within a further p-well 175, which may have a lower doping concentration than the implanted regions 71/73.

In the device 100B, drain breakdown can be preferentially initiated at the drain-source junction 125B rather than the drain-gate junction in the active area 22 of the device 100A by designing the trench/mesa isolation rings 123 or the edge-termination 126A to breakdown at a slightly lower voltage (e.g., ˜850V vs 900V for a 750V JFET) than the active cell.

In the JFET structure 100B shown in FIGS. 8 and 9 in which a planar termination is used, the same p+block process as used in the termination region can be used to form isolation rings between the gate p-well and source-connected p-well. In both cases, one to three isolation rings may be used to block the gate-source voltage (more integrated space between rings) and drain-source voltage (less space between individual rings) simultaneously.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer having an active region, the semiconductor layer having a first conductivity type;
a plurality of alternating mesa stripes and trenches in the active region;
a source metal layer electrically connected with the plurality of mesa stripes;
an isolation ring adjacent the active region, the isolation ring having a second conductivity type opposite the first conductivity type; and
a doped region in the semiconductor layer, wherein the isolation ring is between the active region and the doped region, the doped region having the second conductivity type and forming a P-N junction with the semiconductor layer;
wherein the source metal layer is electrically connected with the doped region.

2. The semiconductor device of claim 1, wherein the doped region comprises a ring around the isolation ring.

3. The semiconductor device of claim 1, wherein the doped region is provided at a bottom surface of a trench between a pair of semiconductor mesas on the semiconductor layer.

4. The semiconductor device of claim 3, further comprising metal silicide layers on upper surfaces of the plurality of mesa stripes, wherein metal silicide layers are not formed on upper surfaces of the pair of semiconductor mesas.

5. The semiconductor device of claim 1, further comprising a metal silicide layer on the doped region, wherein the source metal layer contacts the metal silicide layer.

6. The semiconductor device of claim 1, further comprising an edge termination region adjacent the doped region.

7. The semiconductor device of claim 6, wherein the edge termination region encircles the active region and the doped region.

8. A junction field effect semiconductor device, comprising:
a semiconductor layer having an active region, the semiconductor layer having a first conductivity type;
a plurality of alternating mesa stripes and trenches in the active region;
a plurality of gate regions in respective ones of the trenches;
a source metal layer electrically connected with the plurality of mesa stripes; and
a doped region in the semiconductor layer adjacent the active region, the doped region having a second conductivity type opposite the first conductivity type and forming a P-N junction with the semiconductor layer;
wherein the source metal layer is electrically connected with the doped region.

9. The semiconductor device of claim 8, further comprising:
an isolation ring adjacent the active region, the isolation ring having a second conductivity type opposite the first conductivity type;
wherein the isolation ring is between the doped region and the active region.

10. The semiconductor device of claim 9, wherein the doped region comprises a ring around the isolation ring.

11. The semiconductor device of claim 9, wherein the doped region is provided at a bottom surface of a trench between a pair of semiconductor mesas on the semiconductor layer.

12. The semiconductor device of claim 11, further comprising metal silicide layers on upper surfaces of the plurality of mesa stripes, wherein metal silicide layers are not formed on upper surfaces of the pair of semiconductor mesas.

13. The semiconductor device of claim 9, further comprising a metal silicide layer on the doped region, wherein the source metal layer contacts the metal silicide layer.

14. The semiconductor device of claim 7, further comprising an edge termination region surrounding the doped region.

15. A semiconductor device, comprising:
a semiconductor layer having an active region, the semiconductor layer having a first conductivity type;
a plurality of alternating mesa stripes and trenches in the active region;
a source metal layer electrically connected with the plurality of mesa stripes;
a doped region in the semiconductor layer outside the active region, the doped region having a second conductivity type opposite the first conductivity type and forming a P-N junction with the semiconductor layer, wherein the source metal layer is electrically connected with the doped region; and
an edge termination region adjacent the doped region.

16. The semiconductor device of claim 15, further comprising an isolation ring adjacent the active region, the isolation ring having a second conductivity type opposite the first conductivity type, wherein the isolation ring is between the active region and the doped region.

17. A semiconductor device, comprising:
a semiconductor layer having an active region, the semiconductor layer having a first conductivity type;
a plurality of alternating mesa stripes and trenches in the active region;
a source metal layer electrically connected with the plurality of mesa stripes;
an isolation ring adjacent the active region, the isolation ring having a second conductivity type opposite the first conductivity type;
an edge termination adjacent the isolation ring; and
a doped region in the semiconductor layer outside the active region, the doped region having the second conductivity type and forming a P-N junction with the semiconductor layer, wherein the source metal layer is electrically connected with the doped region, and wherein the isolation ring is between the active region and the doped region.

18. The semiconductor device of claim 17, wherein the doped region comprises a ring around the isolation ring.

19. The semiconductor device of claim 17, wherein the doped region is provided at a bottom surface of a trench between a pair of semiconductor mesas on the semiconductor layer.

20. The semiconductor device of claim 17, further comprising a metal silicide layer on the doped region, wherein the source metal layer contacts the metal silicide layer.

21. The semiconductor device of claim 17, wherein the edge termination comprises a planar edge termination.

22. The semiconductor device of claim 17, wherein the edge termination comprises a plurality of alternating trenches and mesas, and implanted regions beneath the trenches, wherein the implanted regions have the second conductivity type.
